(19) United States
(12) Patent Application Publication
(10) Pub. No.: US 2023/0098901 A1
(43) Pub. Date: Mar. 30, 2023

(54) SEMICONDUCTOR DEVICE, BATTERY MONITORING SYSTEM, MEASUREMENT METHOD, AND EQUALIZATION METHOD

(71) Applicant: LAPIS Technology Co., Ltd., Yokohama (JP)

(72) Inventor: Takatsugu KAI, Yokohama (JP)

(73) Assignee: LAPIS Technology Co., Ltd., Yokohama (JP)

(21) Appl. No.: 17/946,038

(22) Filed: Sep. 16, 2022

(30) Foreign Application Priority Data
Sep. 29, 2021 (JP) 2021-159540

(51) Int. Cl. G01R 31/3835; G01R 31/364

(52) U.S. Cl. CPC G01R 31/3835; G01R 31/364

(57) ABSTRACT

An increase in the load of the booster circuit may be suppressed, and the voltage measurement accuracy may be improved. A battery monitoring IC of a battery monitoring system includes a first buffer amplifier and a second buffer amplifier driven by a power supply voltage or a boost voltage and having an input terminal connected to one terminal of any one of battery cells of an assembled battery. The control part selects the battery cell to be connected to the input terminals of the first and second buffer amplifiers. The control part switches a voltage for driving the first and second buffer amplifiers to the boost voltage when an upper battery cell is selected, and switches the voltage for driving the first and second buffer amplifiers to the power supply voltage when a battery cell other than the upper battery cell is selected.

### CROSS REFERENCE TO RELATED APPLICATIONS

This application claims priority under 35 USC 119 from Japanese Patent application 2021-159540 filed on Sep. 29, 2021, the disclosure of which is incorporated by reference herein.

### BACKGROUND

### Technical Field

The disclosure relates to a semiconductor device, a battery monitoring system, a measurement method, and an equalization method.

### Related Art

Generally, there are battery monitoring semiconductor devices for monitoring and controlling a battery cell. As such a battery monitoring semiconductor device, for example, a battery monitoring integrated circuit (IC) for monitoring and controlling a battery cell mounted on a vehicle or the like is known.

In the battery monitoring IC, the battery voltage on the high potential side of the battery cell and the battery voltage on the low potential side are compared by a comparison part such as an analog level shifter, and the battery voltage of the battery cell is measured based on the difference between the two voltages. Here, the measurement accuracy of the battery voltage is improved by inputting the battery voltage to the comparison part via a buffer amplifier.

For the power supply voltage that drives the buffer amplifier of the battery monitoring IC used at this time, the input voltage input from the high potential side of the battery cell to be monitored (the highest potential side when there are multiple battery cells) may be used. In this case, an offset voltage may occur in the output voltage of the buffer amplifier, and the measurement accuracy of the battery voltage may decrease.

In this regard, Japanese Patent Application Laid-Open No. 2017-118055 describes a battery monitoring system including a booster circuit that boosts the voltage from the same potential as the input voltage. In the technique described in Japanese Patent Application Laid-Open No. 2017-118055, the buffer amplifier is driven by a power supply voltage boosted by the booster circuit from the same potential as the input voltage, thereby suppressing the offset voltage generated in the output voltage of the buffer amplifier and improving the measurement accuracy of the battery voltage.

In order to improve the effective battery capacity, the battery monitoring IC is required to improve the voltage measurement accuracy. Further, in order to monitor many battery cells in a short cycle, high speed measurement is required.

Here, it is necessary to increase the current in order to increase the speed and accuracy of the circuit. In addition, if the system measurement cycle is shortened and functional safety is improved by multi-tracking the measurement path, the current increases due to the increase in circuit blocks.

In order to cope with the increase in the load current of the boost power supply, it is necessary to increase the transfer charge of the booster circuit, and it is necessary to increase the boost voltage width or the boost capacity. When it is shared with an existing circuit, a new voltage output circuit is required to change the boost voltage width, and the cost increases due to the increase in chip area. In addition, the cost of external parts increases due to the increase in boost capacity. Further, in both cases of an increase in the boost voltage width and an increase in the boost capacity, it is necessary to reduce the on-resistance of the switching element, and the chip cost increases due to the increase in the area of the switching element.

In view of the above, the disclosure provides a semiconductor device, a battery monitoring system, a measurement method, and an equalization method capable of suppressing an increase in the load of a booster circuit and improving voltage measurement accuracy.

### SUMMARY

In view of the above, a semiconductor device according to a first embodiment of the disclosure includes: a buffer amplifier that is driven by a power supply voltage or a boost voltage higher than the power supply voltage, and has an input terminal connected to one terminal of any one of multiple battery cells of an assembled battery in which the multiple battery cells are connected in series; a selection part that selects the battery cell to be connected to the input terminal of the buffer amplifier from the multiple battery cells; and a switching part that switches a voltage for driving the buffer amplifier to the boost voltage when an upper battery cell is selected by the selection part, and switches the voltage for driving the buffer amplifier to the power supply voltage when a battery cell other than the upper battery cell is selected by the selection part.

A semiconductor device according to a second embodiment of the disclosure includes: a selection part that selects at least one battery cell as a used cell from multiple battery cells of an assembled battery in which the multiple battery cells are connected in series; and a switching element provided for each of the multiple battery cells. The switching element makes the battery cell driven by a power supply voltage or a boost voltage higher than the power supply voltage and not selected as the used cell into an unused cell. The switching element provided for an upper battery cell is driven by the boost voltage. The switching element provided for a battery cell other than the upper battery cell is driven by the power supply voltage. The selection part selects the upper battery cell as the used cell with priority.

Further, a battery monitoring system according to a third embodiment of the disclosure includes: an assembled battery in which multiple battery cells are connected in series; the above-described semiconductor device; and a diagnosis part that instructs the semiconductor device to measure a battery voltage of the battery cell.

Further, a measurement method according to the disclosure is a measurement method for measuring a voltage of each of multiple battery cells in an assembled battery in which the multiple battery cells are connected in series. The measurement method includes: selecting a measurement target cell from the multiple battery cells; connecting a terminal of the measurement target cell to an input terminal of a first buffer amplifier which is driven by a power supply voltage or a boost voltage higher than the power supply voltage and has the input terminal to be connected any one of the multiple battery cells; connecting another terminal of the measurement target cell to an input terminal of a second buffer amplifier which is driven by the power supply voltage or the boost voltage and has the input terminal to be connected to any one of the multiple battery cells; measuring a voltage of the measurement target cell by comparing an output of the first buffer amplifier with an output of the second buffer amplifier; switching a voltage for driving the first buffer amplifier to the boost voltage when a battery cell connected to the input terminal of the first buffer amplifier is an upper battery cell, and switching the voltage for driving the first buffer amplifier to the power supply voltage when the battery cell connected to the input terminal of the first buffer amplifier is a battery cell other than the upper battery cell; and switching a voltage for driving the second buffer amplifier to the boost voltage when a battery cell connected to the input terminal of the second buffer amplifier is the upper battery cell, and switching the voltage for driving the second buffer amplifier to the power supply voltage when the battery cell connected to the input terminal of the second buffer amplifier is a battery cell other than the upper battery cell.

Further, an equalization method according to the disclosure is an equalization method for equalizing a voltage of each of multiple battery cells in an assembled battery in which the multiple battery cells are connected in series. The equalization method includes: selecting at least one battery cell from the multiple battery cells as a used cell with priority given to an upper battery cell; driving a switching element for making each of the battery cells not selected as the used cell into an unused cell by a power supply voltage or a boost voltage higher than the power supply voltage; selecting a measurement target used cell; connecting a terminal of the measurement target used cell to an input terminal of a first buffer amplifier which is driven by the power supply voltage or the boost voltage and has the input terminal to be connected to any one of the multiple battery cells; connecting another terminal of the measurement target used cell to an input terminal of a second buffer amplifier which is driven by the power supply voltage or the boost voltage and has the input terminal to be connected to any one of the multiple battery cells; and measuring a voltage of the measurement target used cell by comparing an output of the first buffer amplifier with an output of the second buffer amplifier, and turning on or off the switching element of the measurement target used cell so that the voltage of the measurement target used cell is within a predetermined range. The switching element provided for the upper battery cell is driven by the boost voltage. The switching element provided for a battery cell other than the upper battery cell is driven by the power supply voltage.

### Effects

According to the disclosure, it is possible to suppress an increase in the load of the booster circuit and improve the voltage measurement accuracy.

### BRIEF DESCRIPTION OF THE DRAWINGS

FIG. 1 is a circuit diagram of an example of a battery monitoring IC according to the first embodiment.

FIG. 2 is a circuit diagram of a specific example of an internal circuit on the output terminal side of the first buffer amplifier and the second buffer amplifier.

FIG. 3 is a flowchart of an example of a flow of battery voltage diagnosis processing in the battery monitoring IC of this embodiment.

FIG. 4 is a circuit diagram of an example of a part of the circuit of the battery monitoring IC according to the second embodiment.

FIG. 5 is a flowchart of an example of a flow of battery voltage equalization processing in the battery monitoring IC of the second embodiment.

### DESCRIPTION OF EMBODIMENTS

Hereinafter, a battery monitoring system and a semiconductor device for battery monitoring (hereinafter referred to as “battery monitoring IC”) of this embodiment will be described in detail with reference to the drawings. The battery monitoring system (battery monitoring IC) of this embodiment may be applied to a product using a battery LSI (assembled battery or the like), and products such as a personal computer, a car, a motorcycle, a power tool, and the like.

### First Embodiment

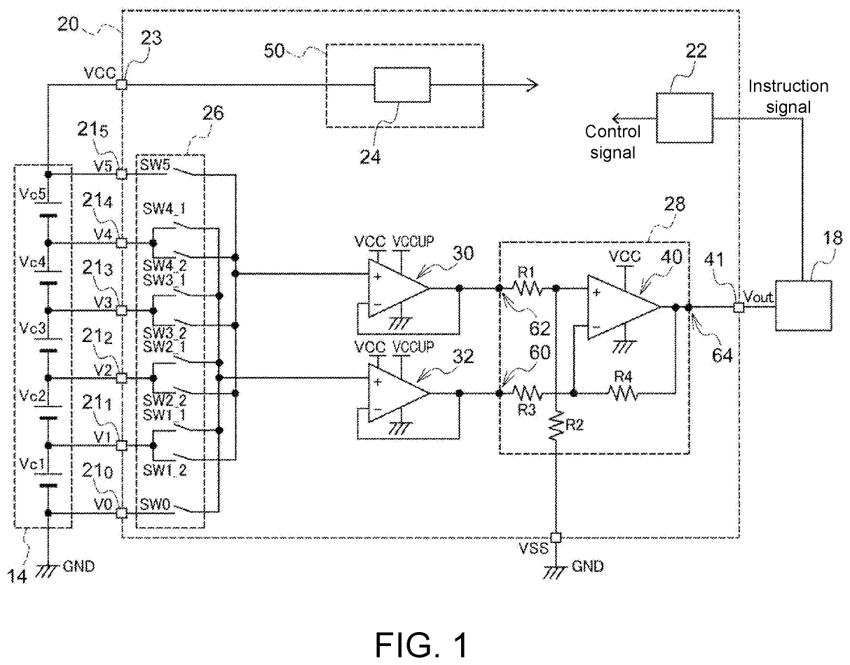

The detailed configuration of the battery monitoring IC 20 of this embodiment will be described. FIG. 1 shows a circuit diagram of an example of an assembled battery 14, a battery monitoring IC 20, and a diagnosis part 18 of this embodiment.

The assembled battery 14 includes five battery cells Vc1 to Vc5 (collectively referred to as the “battery cells Vc”) connected in series. The battery cells Vc1 to Vc5 are connected in series with the battery cell Vc1 at the bottom and the battery cell Vc5 at the top. Specific examples of the battery cells Vc include a nickel-metal hydride battery, a lithium-ion battery, and the like. In FIG. 1, the case where n=5, which is the number of battery cells Vc of the assembled battery 14, is shown as a specific example, but the number n of the battery cells Vc included in the assembled battery 14 is not particularly limited.

Each of the battery cells Vc1 to Vc5 is connected to the battery monitoring IC 20. For example, the voltage V0 on the low potential side of the battery cell Vc1 is input to an input terminal 21₀ of the battery monitoring IC 20. Further, the voltage V1 on the high potential side of the battery cell Vc1, which is synonymous with the voltage on the low potential side of the battery cell Vc2, is input to an input terminal 21₁.

Further, the high potential side of the battery cell Vc5 is connected to a power supply terminal 23 of the battery monitoring IC 20.

The battery monitoring IC 20 includes a control part 22, a booster part 50, a cell selection SW 26, a comparison part 28, a first buffer amplifier 30, and a second buffer amplifier 32. The control part 22 is an example of a switching part.

The booster part 50 has a function of outputting a boosted voltage VCCUP that boosts the power supply voltage VCC input to one terminal from the power supply terminal 23 from the other terminal. The booster part 50 includes a booster circuit 24. The power supply voltage VCC corresponding to the maximum potential of the assembled battery 14 is input to one terminal of the booster part 50 via the power supply terminal 23. The booster circuit 24 boosts the power supply voltage VCC to the boost voltage VCCUP (VCC<VCCUP). The booster part 50 has a function of supplying the boost voltage VCCUP boosted by the booster circuit 24 to the first buffer amplifier 30 and the second buffer amplifier 32 from the other terminal. As a specific example, the booster part 50 of this embodiment outputs the boost voltage VCCUP (VCC+5=VCCUP) obtained by boosting by about 5V the power supply voltage VCC input to one terminal from the other terminal. Further, the power supply voltage VCC is also supplied to the first buffer amplifier 30 and the second buffer amplifier 32.

The cell selection SW 26 includes switching elements SW0, SW1_1, SW1_2, SW2_1, SW2_2, SW3_1, SW3_2, SW4_1, SW4_2, and SW5. Hereinafter, when these switching elements included in the cell selection SW 26 are collectively referred to, they are referred to as the “switching elements SW of the cell selection SW 26.”

The switching elements SW of the cell selection SW 26 are turned on or off by a control signal output from the control part 22. Each of the switching elements SW1_2, SW2_2, SW3_2, SW4_2, and SW5 connects the input terminals 21₁ to 21₅ and the non-inverting input terminal of the first buffer amplifier 30 when they are in the on state. Further, each of the switching elements SW0, SW1_1, SW2_1, SW3_1, and SW4_1 connects the input terminals 21₀ to 21₄ and the non-inverting input terminal of the second buffer amplifier 32 when they are in the on state.

The cell selection SW 26 is connected to the non-inverting input terminal of the first buffer amplifier 30. Further, the cell selection SW 26 is connected to the non-inverting input terminal of the second buffer amplifier 32.

The comparison part 28 includes resistance elements R1, R2, R3 and R4, an amplifier 40, input parts 60 and 62, and an output part 64.

The output terminal of the first buffer amplifier 30 is connected to the non-inverting input terminal of the amplifier 40, and the voltage output from the first buffer amplifier 30 is input via the resistance element R1. One terminal of the resistance element R2 is connected between the non-inverting input terminal of the amplifier 40 and the resistance element R1, and the other terminal is connected to GND (reference potential VSS). Further, the output terminal of the second buffer amplifier 32 is connected to the inverting input terminal of the amplifier 40, and the voltage output from the second buffer amplifier 32 is input via the resistance element R3. Further, the output terminal and the inverting input terminal of the amplifier 40 are connected via the resistance element R4.

From the comparison part 28, an output Vout corresponding to the difference between the voltage output from the output terminal of the first buffer amplifier 30 and the voltage output from the second buffer amplifier 32 is output to the diagnosis part 18 via the output terminal 41.

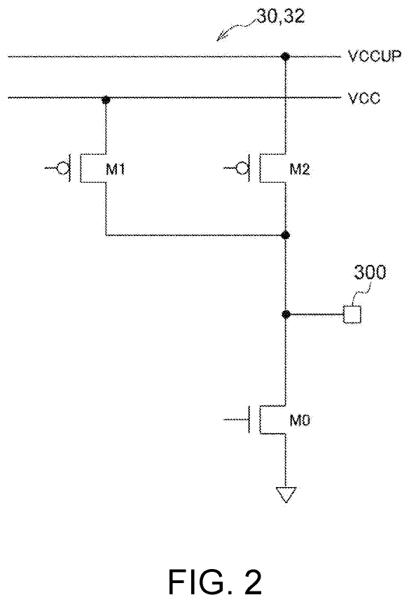

FIG. 2 shows an internal circuit on the output terminal side of the first buffer amplifier 30 and the second buffer amplifier 32. The internal circuits on the output terminal side of the first buffer amplifier 30 and the second buffer amplifier 32 have the same configuration. As shown in FIG. 2, drains of an NMOS transistor MO, a PMOS transistor M1 powered by the power supply voltage VCC, and a PMOS transistor M2 powered by the boost voltage VCCUP are connected to the output terminals 300 of the first buffer amplifier 30 and the second buffer amplifier 32. The PMOS transistor M1 is an example of a first transistor, and the PMOS transistor M2 is an example of a second transistor.

Only one of the PMOS transistors M1 and M2 operates. Which of the PMOS transistors M1 and M2 is operated is switched by the control signal output from the control part 22.

When the PMOS transistor M2 is operated, the PMOS transistor M1 is powered down. In addition, when the PMOS transistor M1 is operated, the PMOS transistor M2 is powered down.

Next, the operation of the battery monitoring IC 20 of this embodiment will be described.

First, the diagnosis of the battery voltage of the battery cells Vc1 to Vc5 by the battery monitoring IC 20 of this embodiment will be described. The timing of performing the diagnosis is not particularly limited, but may be performed periodically, for example, at every predetermined timing.

In the diagnosis part 18 of the battery monitoring system of this embodiment, the battery voltage is measured for each of the battery cells Vc1 to Vc5 as a measurement target.

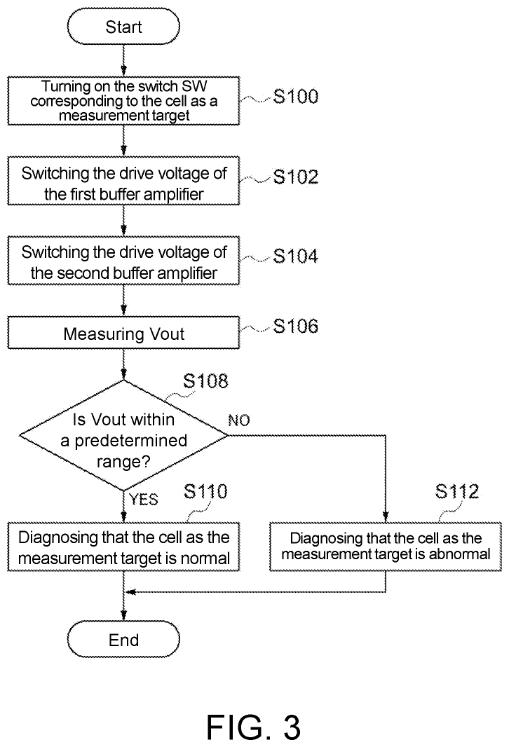

FIG. 3 shows an example of a flow of battery voltage diagnosis processing in the diagnosis part 18. The battery voltage diagnosis processing is repeatedly performed for each of the battery cells Vc1 to Vc5 as a measurement target.

In step S100, the on/off of the switching elements SW of the cell selection SW 26 is controlled according to a battery cell as a measurement target among the battery cells Vc1 to Vc5 as measurement targets by the control signal output from the control part 22. For example, when the voltage value (V2−V1=Vc2) of the battery cell Vc2 is to be measured, the switching elements SW1_1 and SW2_2 of the cell selection SW 26 are turned on, and the other switching elements SW are turned off. Further, when the voltage value (V5−V4=Vc5) of the battery cell Vc5 is to be measured, the switching elements SW4_1 and SW5 of the cell selection SW 26 are turned on, and the other switching elements SW are turned off.

Next, in step S102, the drive voltage of the first buffer amplifier 30 is switched by the control signal output from the control part 22. For example, when the voltage value of an upper battery cell (for example, the battery cell Vc4 or the battery cell Vc5) is to be measured, the drive voltage of the first buffer amplifier 30 is switched to the boost voltage VCCUP by operating the PMOS transistor M2. When the voltage value of a battery cell (for example, the battery cell Vc1 to the battery cell Vc3) other than the upper battery cell is to be measured, the drive voltage of the first buffer amplifier 30 is switched to the power supply voltage VCC by operating the PMOS transistor M1.

Next, in step S104, the drive voltage of the second buffer amplifier 32 is switched by the control signal output from the control part 22. For example, when the voltage value of an upper battery cell (for example, the battery cell Vc4 or the battery cell Vc5) is to be measured, the drive voltage of the second buffer amplifier 32 is switched to the boost voltage VCCUP by operating the PMOS transistor M2. When the voltage value of a battery cell (for example, the battery cell Vc1 to the battery cell Vc3) other than the upper battery cell is to be measured, the drive voltage of the second buffer amplifier 32 is switched to the power supply voltage VCC by operating the PMOS transistor M2.

Next, in step S106, the output Vout is measured.

The voltage output from the first buffer amplifier 30 is input to the non-inverting input terminal of the amplifier 40 of the comparison part 28. In addition, the voltage output from the second buffer amplifier 32 is input to the inverting input terminal of the amplifier 40.

Therefore, a voltage corresponding to the difference between the voltage output from the first buffer amplifier 30 and the voltage output from the second buffer amplifier 32 is output from the amplifier 40 as the output Vout to the diagnosis part 18. For example, when the voltage value of the battery cell Vc5 is to be measured, a voltage corresponding to the difference between the voltage V5 output from the first buffer amplifier 30 and the voltage V4 output from the second buffer amplifier 32 is output as the output Vout to the diagnosis part 18. The diagnosis part 18 measures the output Vout.

Next, in step S108, it is determined whether the output Vout is within a predetermined range. For example, when the voltage of the battery cell as a measurement target is normal, the output Vout becomes a voltage predetermined for the battery cell as a measurement target. Therefore, when the output Vout is within a predetermined range from the voltage predetermined for the battery cell as the measurement target, with the allowable range obtained by experiments and the like taken into account, the diagnosis part 18 determines that the voltage of the battery cell as the measurement target is normal.

If the output Vout is within the predetermined range, a positive determination is made and the process proceeds to step S110. After diagnosing that the voltage of the battery cell as the measurement target is normal in step S110, the diagnosis part 18 ends the battery voltage diagnosis processing.

In addition, if the output Vout is not within the predetermined range (outside the range), a negative determination is made and the process proceeds to step S112. After diagnosing that the voltage of the battery cell as the measurement target is abnormal in step S112, the diagnosis part 18 ends the battery voltage diagnosis processing.

As described above, according to the battery monitoring IC of this embodiment, the battery cells connected to the input terminals of the first buffer amplifier and the second buffer amplifier are selected from multiple battery cells; when an upper battery cell is selected, the voltage for driving the first buffer amplifier and the second buffer amplifier is switched to the boost voltage; and when a battery cell other than the upper battery cell is selected, the voltage for driving the first buffer amplifier and the second buffer amplifier is switched to the power supply voltage. As a result, it is possible to suppress an increase in the load of the booster circuit and improve the voltage measurement accuracy.

In addition, by switching the voltage for driving the buffer amplifier in a time division manner, the usage time of the boost voltage is limited, whereby the average load current to the booster circuit is reduced, and the required characteristics for the booster circuit are minimized. As a result, the required capacity of the booster circuit may be reduced, and the area may be reduced.

Further, the power supply voltage and the boost voltage are properly used as the drive voltage according to the battery cell selected as the measurement target. For the buffer amplifier, the power supply voltage corresponding to the highest potential of the assembled battery is used as the drive voltage, and the accuracy of the output voltage deteriorates only when the output potential and the input potential are close to the power supply voltage, and when the selected cell is the upper battery cell. When the selected cell is a lower battery cell, there is no problem even if the power supply voltage is used as the drive voltage. Therefore, by switching the drive voltage according to the selected cell, it is possible to limit the cells that supply the boost voltage and reduce the average load current of the booster circuit when all the battery cells are continuously measured.

### Second Embodiment

Next, the battery monitoring IC according to the second embodiment will be described. The parts having the same configuration as that of the first embodiment are designated by the same reference numerals, and the description thereof will be omitted.

The second embodiment is different from the first embodiment in that the used cells among the assembled battery may be selected and that the voltage equalization processing of the used cells is performed.

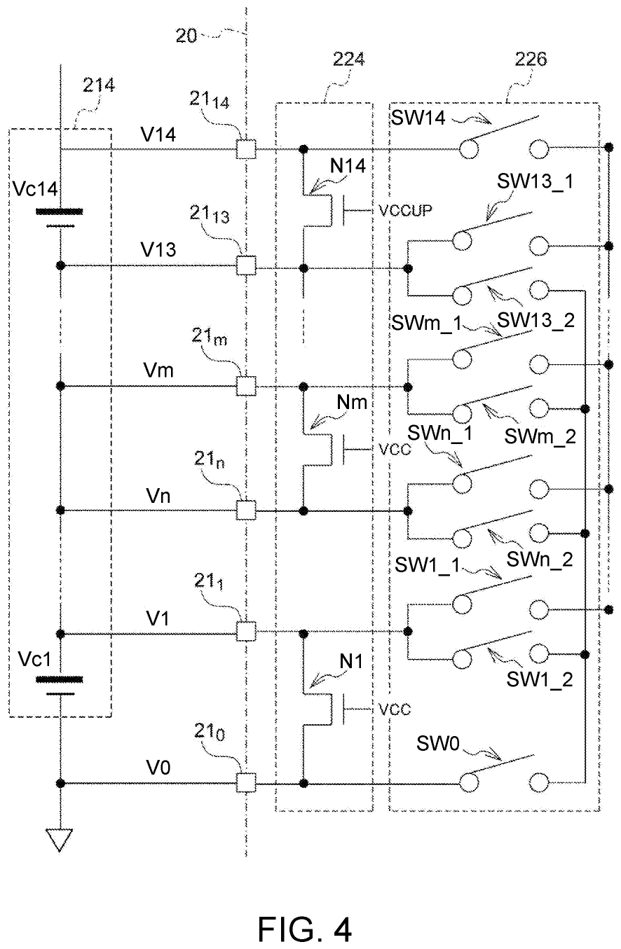

FIG. 4 shows a circuit diagram a part of an assembled battery 214 and the battery monitoring IC 20 of this embodiment.

An equalization NMOS 224 is provided between the cell selection SW 26 of the battery monitoring IC 20 and the assembled battery 214.

Though not shown, the battery monitoring IC 20 further includes a control part 22, a booster part 50, a comparison part 28, a first buffer amplifier 30, and a second buffer amplifier 32, as in the first embodiment. The control part 22 is an example of a selection part.

The assembled battery 214 includes ten battery cells Vc1 to Vc14 (collectively referred to as the “battery cells Vc”) connected in series. The battery cells Vc1 to Vc14 are connected in series with the battery cell Vc1 at the bottom and the battery cell Vc14 at the top. In FIG. 4, the case the number of battery cells Vc of the assembled battery 214 is 14 shown as a specific example, but the number of the battery cells Vc included in the assembled battery 214 is not particularly limited.

Each of the battery cells Vc1 to Vc14 is connected to the battery monitoring IC 20. For example, the voltage V0 on the low potential side of the battery cell Vc1 is input to an input terminal 21₀ of the battery monitoring IC 20. Further, the voltage V1 on the high potential side of the battery cell Vc1, which is synonymous with the voltage on the low potential side of the battery cell Vc2, is input to an input terminal 21₁.

The cell selection SW 226 includes switching elements SW0, SW1_1, SW1_2, SW2_1, SW2_2, . . . , SW13_1, SW13_2, and SW14. Hereinafter, when these switching elements included in the cell selection SW 226 are collectively referred to, they are referred to as the “switching elements SW of the cell selection SW 226.”

The switching elements SW of the cell selection SW 226 are turned on or off by a control signal output from the control part 22. Each of the switching elements SW1_1, SW2_1, . . . , SW13_1, and SW14 connects the input terminals 21₁ to 21₁₄ and the non-inverting input terminal of the first buffer amplifier 30 when they are in the on state. Further, each of the switching elements SW0, SW1_2, SW2_2, . . . , SW13_2 connects the input terminals 21₀ to 21₁₃ and the non-inverting input terminal of the second buffer amplifier 32 when they are in the on state.

The equalization NMOS 224 includes NMOS transistors N1 to N14 (collectively referred to as the “NMOS transistors N”) for making a battery cell driven by a power supply voltage or a boost voltage and not selected as a used cell into an unused cell. The NMOS transistors N1 to N14 are provided corresponding to the battery cells Vc1 to Vc14. The NMOS transistors N1 to N14 are examples of switching elements for making a battery cell an unused cell.

In this embodiment, for the upper battery cells (for example, the battery cells Vc13 to Vc14), the NMOS transistors N are driven by the boost voltage VCCUP; and for the battery cells (for example, the battery cells Vc1 to Vc12) other than the upper battery cells, the NMOS transistors N are driven by the power supply voltage VCC. Further, by driving the NMOS transistors N corresponding to the unused battery cells Vc, two terminals of the unused battery cells Vc are short-circuited. For example, when the battery cells Vcn to Vcm are unused cells, the NMOS transistors Nn to Nm are driven and short-circuited to connect the battery cells Vcn−1 and Vcm+1. Since the potentials have become the same outside the battery monitoring IC 20, it is not necessary to short-circuit between two terminals of the unused battery cells Vc by the corresponding NMOS transistors N.

The control part 22 selects the upper battery cell Vc as the used cell with priority.

Here, the reason why the upper battery cell is selected as the used cell with priority by the control part 22 will be described.

When the cell voltage of the battery cells Vc is equalized, in a case where two terminals of the uppermost battery cell Vc14 are short-circuited by the NMOS transistor N14, the source side becomes close to the power supply voltage, and the power supply voltage is insufficient as the gate voltage for turning on the NMOS transistor N14; therefore, the boost voltage is required. When short-circuiting between two terminals of the lower battery cell with the NMOS transistor N, the power supply voltage is sufficient; therefore, the boost voltage is required for the uppermost battery cell and the nearby battery cell.

Further, when the number of used cells is variable and the number of used cells is small, if a short circuit is made between two terminals as an unused cell from the upper side, the number of the driven NMOS transistors N increases according to the number of selections; therefore, the load current of the boost power supply becomes large.

For example, when the boost voltage is required when short-circuiting two terminals of the upper two battery cells and the number of used cells is variable between 7 and 14, if the upper two battery cells are regarded as unused cells and the two terminals are short-circuited, the load current of the boost power supply becomes large.

Therefore, in this embodiment, the control part 22 selects the upper battery cell as used cells with priority. For example, when the number of used cells is variable and the number of used cells is small, the two terminals of an intermediate battery cell (for example, battery cells Vcm to Vcn) using the power supply voltage VCC as the drive power source of the NMOS transistor are short-circuited.

Further, when the battery voltage of the used cell is to be equalized, the battery voltage of the used cell is adjusted to be within a predetermined range by turning on or off the corresponding NMOS transistor N.

Next, the operation of the battery monitoring IC 20 of this embodiment will be described.

First, the equalization of the battery voltage of the battery cells Vc1 to Vc14 by the battery monitoring IC 20 of this embodiment will be described. The timing of performing the equalization is not particularly limited, but may be performed periodically, for example, at every predetermined timing.

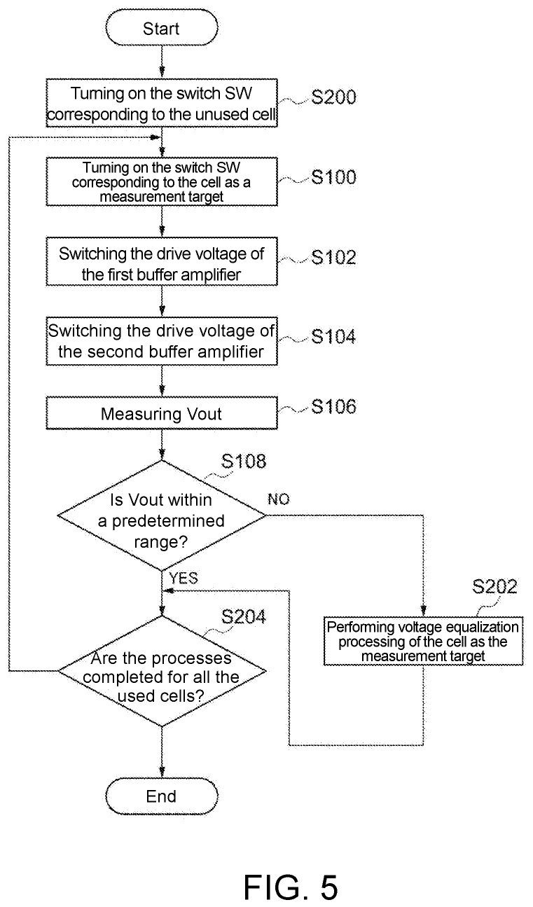

FIG. 5 shows an example of the flow of the battery voltage equalization process in the diagnosis part 18 of the battery monitoring system of this embodiment. Here, it is assumed that the number of used cells is set. Further, the same processing as in the first embodiment is designated by the same reference numerals, and detailed description thereof will be omitted.

In step S200, according to the control signal output from the control part 22, the upper battery cell Vc is prioritized and selected as the used cell according to the number of used cells, and the NMOS transistor N corresponding to the unused cell is turned on. At this time, when a battery cell Vc other than the upper battery cell Vc becomes the unused cell, the corresponding NMOS transistor N is driven by the power supply voltage VCC. When the upper battery cell Vc is also an unused cell, the boost voltage VCCUP drives the corresponding NMOS transistor N.

In step S100, the on/off of the switching elements SW of the cell selection SW 226 is controlled according to a battery cell Vc as a measurement target among the used cells by the control signal output from the control part 22.

Next, in step S102, the drive voltage of the first buffer amplifier 30 is switched by the control signal output from the control part 22.

Next, in step S104, the drive voltage of the second buffer amplifier 32 is switched by the control signal output from the control part 22.

Next, in step S106, the output Vout is measured.

Next, in step S108, it is determined whether the output Vout is within a predetermined range. If the output Vout is within the predetermined range, a positive determination is made and the process proceeds to step S204. In addition, if the output Vout is not within the predetermined range (outside the range), a negative determination is made and the process proceeds to step S202.

In step S202, the diagnosis part 18 outputs a control signal from the control part 22 according to the voltage of the battery cell Vc as the measurement target, and adjusts the battery voltage of the battery cell Vc as the measurement target to be within a predetermined range by turning on or off the NMOS transistor N corresponding to the battery cell Vc as the measurement target.

In step S204, the diagnosis part 18 determines whether the processes of steps S100 to S202 have been performed on all the used cells as the measurement targets. If there is a used cell on which the processes of steps S100 to S202 have not been performed, the process returns to step S100 with the used cell as the measurement target.

In addition, when the processes of steps S100 to S202 have been performed on all the used cells as the measurement targets, the battery voltage equalization processing ends.

As described above, according to the battery monitoring IC of this embodiment, the upper battery cell is selected as the used cell from the assembled battery with priority, and the switching element provided for the upper battery cell to make it an unused cell is driven by a boost voltage, and the switching element provided for a battery cell other than the upper battery cell to make it an unused cell is driven by the power supply voltage. As a result, it is possible to suppress an increase in the load of the booster circuit and improve the voltage measurement accuracy.

Further, in the battery voltage equalization processing, a normal cell voltage measurement operation and a normal cell equalization operation are performed. Here, among the NMOS transistors for making the number of cells variable and making unused cells and for battery voltage equalization, only the NMOS transistor for the upper battery cell is driven by the boost voltage, and the upper battery cell is selected as the used cell with priority. In this configuration, when the number of used cells is set to be small, by not using the intermediate battery cell corresponding to the NMOS transistor driven by the power supply voltage, among the battery cells near the uppermost cell corresponding to the NMOS transistor driven by the boost voltage, the unused battery cells are limited to the minimum necessary cells. In this way, the usage time of the boost voltage is limited, whereby the average load current to the booster circuit is reduced, and the required characteristics for the booster circuit are minimized.

What is claimed is:

1. A semiconductor device comprising:
a buffer amplifier that is driven by a power supply voltage or a boost voltage higher than the power supply voltage, and has an input terminal connected to one terminal of any one of a plurality of battery cells of an assembled battery in which the plurality of battery cells are connected in series;
a selection part that selects the battery cell to be connected to the input terminal of the buffer amplifier from the plurality of battery cells; and
a switching part that switches a voltage for driving the buffer amplifier to the boost voltage when an upper battery cell is selected by the selection part, and switches the voltage for driving the buffer amplifier to the power supply voltage when a battery cell other than the upper battery cell is selected by the selection part.

2. The semiconductor device according to claim 1, wherein the buffer amplifier comprises:
a first transistor driven by the power supply voltage; and
a second transistor driven by the boost voltage,
wherein drains of the first transistor and the second transistor are connected to an output terminal.

3. A battery monitoring system comprising:
an assembled battery in which a plurality of battery cells are connected in series;
the semiconductor device according to claim 1; and
a diagnosis part that instructs the semiconductor device to measure a battery voltage of the battery cell.

4. The battery monitoring system according to claim 3, wherein the buffer amplifier comprises:
a first transistor driven by the power supply voltage; and
a second transistor driven by the boost voltage,
wherein drains of the first transistor and the second transistor are connected to an output terminal.

5. A semiconductor device comprising:
a selection part that selects at least one battery cell as a used cell from a plurality of battery cells of an assembled battery in which the plurality of battery cells are connected in series; and
a switching element provided for each of the plurality of battery cells, wherein the switching element makes the battery cell driven by a power supply voltage or a boost voltage higher than the power supply voltage and not selected as the used cell into an unused cell,
wherein the switching element provided for an upper battery cell is driven by the boost voltage,
the switching element provided for a battery cell other than the upper battery cell is driven by the power supply voltage, and
the selection part selects the upper battery cell as the used cell with priority.
